(19) United States
(12) Patent Application Publication
(10) Pub. No.: US 2007/0096183 A1
(43) Pub. Date: May 3, 2007

(54) Semiconductor device and method for fabricating the same

(76) Inventors: Hisashi Ogawa, Osaka (JP); Naoki Kotani, Hyogo (JP); Susumu Akamatsu, Osaka (JP); Chiaki Kudo, Hyogo (JP)

Correspondence Address: MCDERMOTT WILL & EMERY LLP, 600 13TH STREET, N.W., WASHINGTON, DC, 20005-3096, US

(21) Appl. No.: 11/500,940

(22) Filed: Aug. 9, 2006

(30) Foreign Application Priority Data
Oct. 28, 2005 (JP) 2005-315215

(51) Int. Cl. H01L 29/94; H01L 27/108; H01L 21/336; H01L 29/76; H01L 31/119

(52) U.S. Cl. 257/300; 438/268

(57) ABSTRACT

In a semiconductor device including a MIS transistor with a FUSI gate electrode and a polysilicon resistor, a portion of the polysilicon resistor provided in a contact formation region is silicided simultaneously with the gate electrode or an impurity diffusion region.

### BACKGROUND OF THE INVENTION

(a) Fields of the Invention

The present invention relates to semiconductor devices and their fabrication methods. In particular, the present invention relates to semiconductor devices including FUSI (fully silicided) gate electrodes, and to their fabrication methods.

(b) Description of Related Art

In research and development of CMOS devices ever-increasingly miniaturized, active studies are being conducted to employ metal electrodes for the purpose of preventing depletion of gate electrodes. Among these studies, FUSI (fully silicided) gate electrodes are particularly proposed which are each made by fully siliciding a polysilicon electrode to form a silicide electrode.

For these devices, if polysilicon with a relatively high resistance is used for a resistor, a process for attaining the state of connection of the polysilicon resistor to polycide with a low resistance is proposed in a conventional salicide process.

FIGS. 13A to 13C are sectional views showing a method for fabricating a polysilicon resistor by a conventional salicide process described in Japanese Unexamined Patent Publication Ser. No. H5-55215. In the conventional salicide process, as exemplarily shown in FIG. 13A, a polysilicon 103 is formed on an insulating film 102 lying on a silicon substrate 101, and then phosphorus (P) or the like is implanted as an impurity 104. Subsequently, as shown in FIG. 13B, an insulating film 105 is formed on the polysilicon 103. Using the formed insulating film 105 as a mask, the impurity 104 is additionally implanted to form a low-resistance polysilicon portion 103A doped at a high concentration. Next, as shown in FIG. 13C, a silicide 106 is formed by a so-called salicide process, thereby producing a polysilicon resistor and a polycide interconnect having a two-layer structure of the low-resistance polysilicon portion 103A and the silicide 106.

### SUMMARY OF THE INVENTION

However, in the process flow for a FUSI electrode formation, the step of siliciding a diffusion layer and the step of siliciding a polysilicon gate electrode are conducted separately, so that it is difficult to simply fabricate a semiconductor device including the FUSI electrode and the polysilicon resistor.

In view of the foregoing, an object of the present invention is to provide a semiconductor device including a FUSI electrode and a polysilicon resistor and enabling a simple fabrication thereof, and to provide its fabrication method.

A first semiconductor device according to the present invention comprises: a semiconductor substrate; a first MIS transistor which includes: a first gate insulating film provided on the semiconductor substrate; a first gate electrode provided on the first gate insulating film and made of metal silicide; and a first impurity diffusion region formed in a region of the semiconductor substrate located below each side of the first gate electrode; and a resistance element formed over an isolation region provided in the semiconductor substrate and having a resistor of polysilicon. In this device, a contact formation region of the resistance element is formed at least at its top with a first silicide layer.

This structure of the device can prevent depletion of the first gate electrode occurring around the first gate insulating film, and also reduce the contact resistance between the resistance element and the plug. Moreover, the MIS transistor with a so-called FUSI electrode and the polysilicon resistor can be fabricated partly by common steps, which enables a simple fabrication of the semiconductor device.

Furthermore, with the above structure, common steps can be carried out to also form a MIS transistor with an unsilicided gate electrode.

In the case where an entire depthwise portion of the contact formation region of the resistance element is formed of the first silicide layer, the contact formation region can be silicided simultaneously with the first gate electrode. This inhibits expansion of the silicide layer into a portion to be a resistor, so that the resistor can be formed with good controllability.

The first silicide layer may have a greater thickness than the resistor.

A second semiconductor device according to the present invention comprises: a semiconductor substrate; an isolation region provided in the semiconductor substrate; a first MIS transistor which includes: a first gate insulating film provided on the semiconductor substrate; a first gate electrode provided on the first gate insulating film and made of metal silicide; and a first impurity diffusion region formed in a region of the semiconductor substrate located below each side of the first gate electrode; and a second MIS transistor which includes: a second gate insulating film provided on the semiconductor substrate; a second gate electrode of polysilicon provided on the second gate insulating film and formed, at least at the top of a contact formation region thereof, with a silicide layer; and a second impurity diffusion region formed in a region of the semiconductor substrate located below each side of the second gate electrode.

A first method for fabricating a semiconductor device according to the present invention is a method for fabricating a semiconductor device which includes: a first MIS transistor made of metal silicide and having a first gate electrode; and a resistance element having a resistor of polysilicon. This method comprises: the step (a) of forming an isolation region in a semiconductor substrate; the step (b) of forming, after the step (a), a first gate insulating film on the semiconductor substrate; the step (c) of forming, after the step (b), a polysilicon layer over the semiconductor substrate; the step (d) of patterning the polysilicon layer to form a polysilicon layer for the first gate electrode on the first gate insulating film and a polysilicon layer for the resistance element over the isolation region; the step (e) of forming a first impurity diffusion region in a region of the semiconductor substrate located below each side of the polysilicon layer for the first gate electrode; the step (f) of siliciding, after the step (e), at least the top of a contact formation region of the resistance element of the polysilicon layer for the resistance element to form a first silicide layer; and the step (g) of siliciding, after the step (e), the whole of the polysilicon layer for the first gate electrode to form the first gate electrode.

A second method for fabricating a semiconductor device according to the present invention is a method for fabricating a semiconductor device which includes: a first MIS transistor made of metal silicide and having a first gate electrode; and a second MIS transistor having a second gate electrode of polysilicon with a first silicide layer formed at least on the top of a contact formation region. This method comprises: the step (a) of forming an isolation region in a semiconductor substrate; the step (b) of forming, after the step (a), a first gate insulating film and a second gate insulating film on the semiconductor substrate; the step (c) of forming, after the step (b), a polysilicon layer over the semiconductor substrate; the step (d) of patterning the polysilicon layer to form a polysilicon layer for the first gate electrode on the first gate insulating film and a polysilicon layer for the second gate electrode on the second gate insulating film; the step (e) of forming a first impurity diffusion region in a region of the semiconductor substrate located below each side of the polysilicon layer for the first gate electrode and a second impurity diffusion region in a region of the semiconductor substrate located below each side of the polysilicon layer for the second gate electrode; the step (f) of siliciding, after the step (e), at least the top of a contact formation region of the second gate electrode of the polysilicon layer for the second gate electrode to form the first silicide layer; and the step (g) of siliciding, after the step (e), the whole of the polysilicon layer for the first gate electrode to form the first gate electrode.

### BRIEF DESCRIPTION OF THE DRAWINGS

FIG. 1 is a sectional view showing a semiconductor device according to a first embodiment of the present invention.

FIGS. 2A to 2C are sectional views showing a method for fabricating a semiconductor device according to the first embodiment.

FIGS. 3A to 3D are sectional views showing the method for fabricating a semiconductor device according to the first embodiment.

FIGS. 4A to 4C are sectional views showing a method for fabricating a semiconductor device according to the first embodiment.

FIG. 5 is a sectional view showing a semiconductor device according to a second embodiment of the present invention.

FIGS. 6A to 6D are sectional views showing a method for fabricating a semiconductor device according to the second embodiment.

FIGS. 7A to 7C are sectional views showing the method for fabricating a semiconductor device according to the second embodiment.

FIGS. 8A to 8C are sectional views showing a method for fabricating a semiconductor device according to a third embodiment of the present invention.

FIGS. 9A to 9C are sectional views showing a method for fabricating a semiconductor device according to one modification of the third embodiment.

FIG. 10 is a sectional view showing a semiconductor device according to a fourth embodiment of the present invention.

FIG. 11A is a sectional view of a semiconductor device according to a fifth embodiment of the present invention, which is taken along the gate length direction. FIG

FIG. 12A is a sectional view of the semiconductor device in which a gate electrode is taken along the gate width direction.

FIG. 12A is a sectional view of a semiconductor device according to a sixth embodiment of the present invention, which is taken along the gate length direction. FIG. 12B is a sectional view of the semiconductor device in which a gate electrode is taken along the gate width direction.

FIGS. 13A to 13C are sectional views showing a method for fabricating a polysilicon resistor by a conventional salicide process.

### DETAILED DESCRIPTION OF THE PREFERRED EMBODIMENTS

### First Embodiment

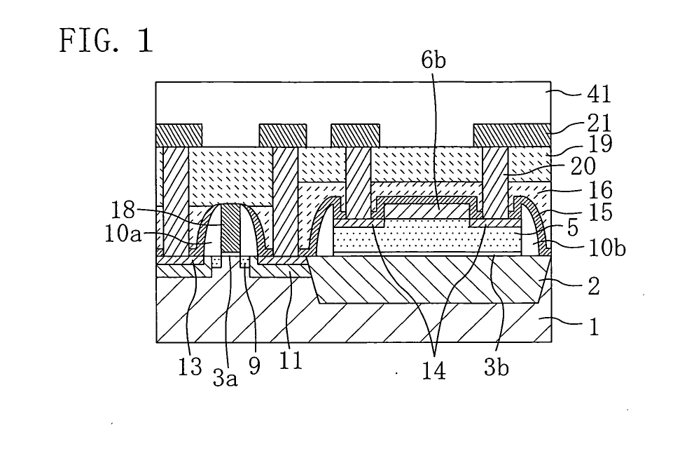

FIG. 1 is a sectional view showing a semiconductor device according to a first embodiment of the present invention. Referring to FIG. 1, the semiconductor device of the first embodiment is characterized in that the device includes a so-called FUSI electrode 18 and a polysilicon resistor with only a connection portion to a plug 20 and its vicinity silicided.

To be more specific, the semiconductor device of the first embodiment includes: a semiconductor substrate 1 made of silicon or the like; an isolation insulating film 2 surrounding an active region of the semiconductor substrate 1 and buried in the semiconductor substrate 1; a MIS (Metal-Insulator-Semiconductor) transistor formed on the active region of the semiconductor substrate 1; and a resistance element having a polysilicon resistor 5 provided above, for example, the isolation insulating film 2 with a first insulating film 3b interposed therebetween. The resistance element is composed of: a resistor region made of the polysilicon resistor 5; and a contact formation region with a silicide layer 14 for the resistor provided on the polysilicon resistor 5. Note that the first insulating film 3b does not necessarily have to be formed below the polysilicon resistor 5.

The MIS transistor includes a gate insulating film 3a, a gate electrode 18, a sidewall 10a, an extension region 9, an impurity diffusion region 11, and a first silicide layer 13. The gate insulating film 3a is provided on the semiconductor substrate 1 and made of a high-k material or the like. The gate electrode 18 is provided on the gate insulating film 3a, and made of Ni silicide such as NiSi. The sidewall 10a is provided on each side surface of the gate electrode 18, and made of an insulative material such as SiO₂. The extension region 9 is formed in a region of the semiconductor substrate 1 located below each side of the gate electrode 18, and contains an n-type impurity at a low concentration. The impurity diffusion region 11 is provided in a region of the semiconductor substrate 1 located below sides of the gate electrode 18 and the sidewall 10a, and serves as a source/drain region containing an n-type impurity at a higher concentration than that of the extension region 9. The first silicide layer 13 is provided on the impurity diffusion region 11, and made of Ni silicide. The first silicide layer 13 is connected through the plug 20 of tungsten (W) or the like to an interconnect 21.

The polysilicon resistor 5 contains an n-type impurity at a low concentration (for example, about 3×10²⁰/cm³). An insulating film 6b on the resistor made of NSG (Non-Doped Silicate Glass) or the like is provided on the polysilicon resistor 5 other than the contact formation region, while the silicide layer 14 for the resistor made of Ni silicide is provided on a portion of the polysilicon resistor 5 which serves as a contact region with the plug 20 and which is not formed with the insulating film 6b on the resistor. A portion of the polysilicon resistor 5 provided below the insulating film 6b on the resistor has a thickness of about 100 nm, while the silicide layer 14 for the resistor has a thickness of about 30 nm. The silicide layer 14 for the resistor and the first silicide layer 13 are silicided simultaneously in the fabrication method, and have almost the same thickness. The silicide layer 14 for the resistor is connected through the plug 20 to the interconnect 21. Although the interconnect 21 connected to the first silicide layer 13 and the interconnect 21 connected to the silicide layer 14 for the resistor are shown by the same reference numeral for descriptive purposes, the two interconnects are discrete. On each surface of the polysilicon resistor 5, a sidewall 10b of an insulative material is provided which is formed simultaneously with, for example, the sidewall 10a.

The semiconductor device of the first embodiment is also formed with a second insulating film 15, a first interlayer insulating film 16, and a second interlayer insulating film 19. The second insulating film 15 is made of a silicon nitride film (Si₃N₄) or the like and covers the first silicide layer 13, the sidewall 10a, the sidewall 10b, the insulating film 6b on the resistor, and the silicide layer 14 for the resistor of the MIS transistor. The first interlayer insulating film 16 is made of NSG or the like and provided on the second insulating film 15. The second interlayer insulating film 19 is made of NSG or the like and provided on the first interlayer insulating film 16. The plug 20 penetrates the second insulating film 15, the first interlayer insulating film 16, and the second interlayer insulating film 19. A third interlayer insulating film 41 is formed on the second interlayer insulating film 19 and the interconnect 21.

In the semiconductor device of the first embodiment, the whole of the gate electrode 18 is silicided, which prevents depletion of the gate electrode 18 occurring around the interface with the gate insulating film 3a. Furthermore, a portion of the impurity diffusion region 11 in contact with the plug 20 is silicided (as the first silicide layer 13), which reduces the contact resistance of the impurity diffusion region 11. Moreover, in the polysilicon resistor 5, a region located below the insulating film 6b on the resistor and interposed between the silicide layers 14 for the resistor acts mainly as a resistor for determining the resistance value of the resistor 5, and a portion in contact with the plug 20 is silicided (as the silicide layer 14 for the resistor) to reduce the contact resistance of the polysilicon resistor 5. Furthermore, the silicide layer 14 for the resistor is formed simultaneously with the first silicide layer 13, which prevents excess silicidation of the polysilicon resistor 5 and provides a well-controllable silicidation of only part of the polysilicon resistor 5.

Next description will be made of a method for fabricating a semiconductor device according to the first embodiment.

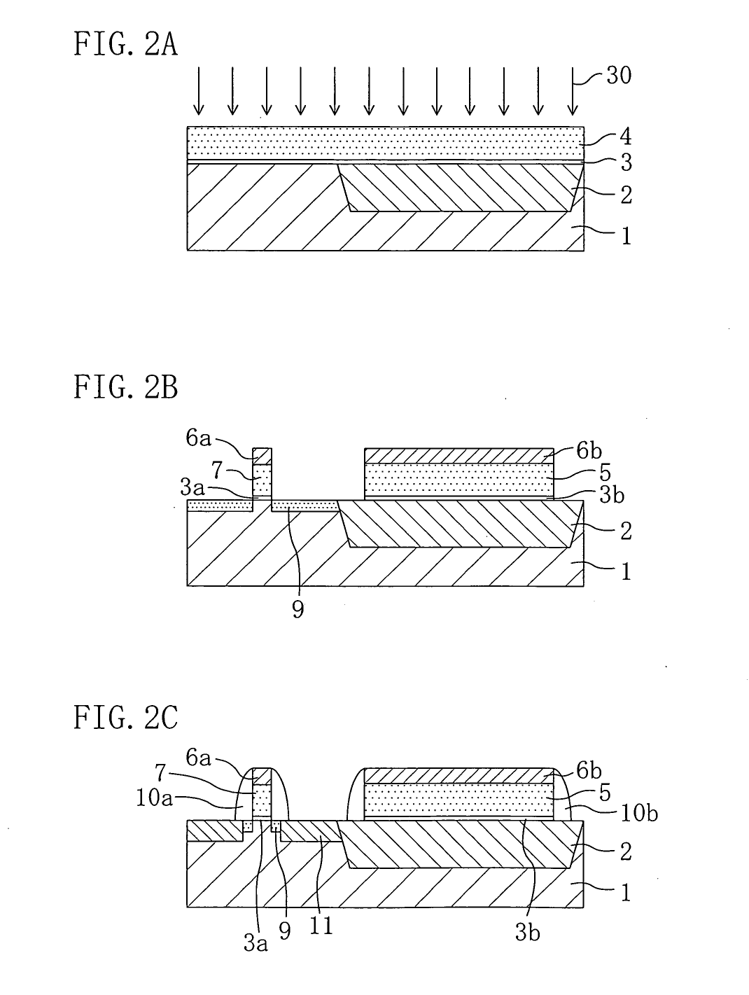

FIGS. 2A to 2C, 3A to 3D, and 4A to 4C are sectional views showing a method for fabricating a semiconductor device according to the first embodiment.

As shown in FIG. 2A, first, the isolation insulating film 2 is formed within a groove provided in the semiconductor substrate 1, and the resulting semiconductor substrate 1 is subjected to ion implantation for well formation, channel stop, channel doping, and the like. Thereafter, the top of the semiconductor substrate 1 is sequentially formed with the insulating film 3 of a high-k material or the like having a thickness of about 3 nm and a polysilicon layer 4 having a thickness of 100 nm, and then, for example, a phosphorus ion 30 as an impurity is implanted into the polysilicon layer 4. This impurity implantation determines the resistance value of the polysilicon resistor.

Next, as shown in FIG. 2B, an insulating film of NSG or the like is deposited on the entire surface of the polysilicon layer 4. Then, the insulating film is partly removed while portions thereof remain which are provided on the areas to be formed with a gate region and a polysilicon resistor (which are formed into an insulating film (protective film) 6a on a gate electrode and an insulating film (protective film) 6b on a resistor, respectively). Using the insulating film 6a on the gate electrode and the insulating film 6b on the resistor as a mask, the polysilicon layer 4 and the insulating film 3 are etched to form a polysilicon gate electrode 7 and the gate insulating film 3a on the active region made of the semiconductor substrate 1 and surrounded with the isolation insulating film 2, and also the polysilicon resistor 5 and the first insulating film 3b on the isolation insulating film 2. In this formation, the first insulating film 3b does not necessarily have to be formed below the polysilicon resistor 5. Then, in the state in which the polysilicon gate electrode 7 with the insulating film (protective film) 6a on the gate electrode provided at its top is used as a mask, an n-type impurity is implanted into a portion of the active region of the semiconductor substrate 1 located below each side surface of the polysilicon gate electrode at a dose of about 1×10¹⁵/cm², thereby forming the extension region 9.

As shown in FIG. 2C, by a publicly known technique, the sidewall 10a of an insulating material is formed on each side surface of the polysilicon gate electrode 7, and the sidewall 10b is formed on each side surface of the polysilicon resistor 5. Then, an n-type type impurity ion such as arsenic (As) is implanted at a dose of 4×10¹⁵/cm² to form an impurity diffusion region 11 as a source/drain region in a region of the semiconductor substrate 1 located below the sides of the polysilicon gate electrode 7 and the sidewall 10a. Although not shown, in a PMOS formation region, the polysilicon gate electrode and the sidewall are formed, and then a p-type impurity is implanted using them as a mask to form a p-type impurity diffusion region as a source/drain region containing the p-type impurity.

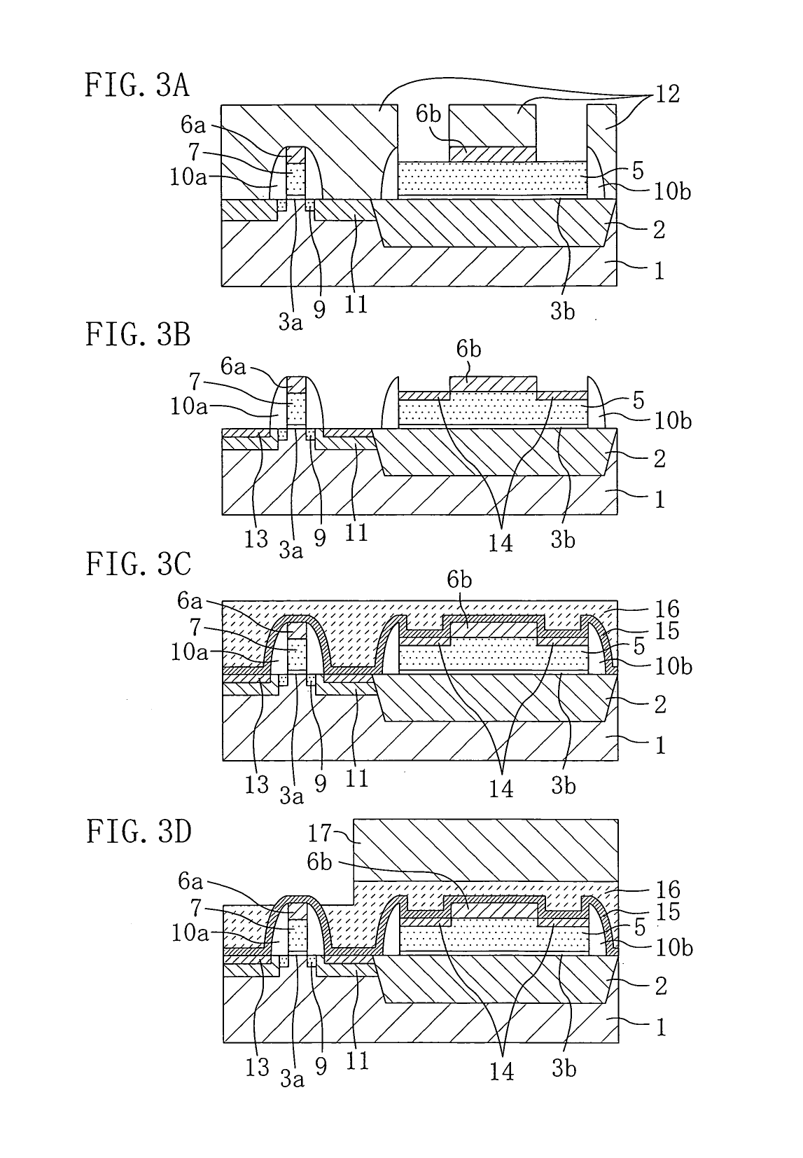

Next, as shown in FIG. 3A, a first photoresist pattern 12 having openings provided through only portions thereof including the contact formation regions of the polysilicon resistor 5 is formed over the substrate. Thereafter, using the first photoresist pattern 12 as a mask, portions of the insulating film 6b on the resistor are selectively removed which interpose an area lying on the resistor region of the polysilicon resistor 5.

Subsequently, as shown in FIG. 3B, the first photoresist pattern 12 is removed, and then over the entire surface of the substrate, for example, a Ni film with a thickness of 11 nm is deposited by a sputtering method or the like. The resulting semiconductor substrate 1 is subjected to rapid thermal annealing (RTA) at 320° C., which allows Ni to react with silicon to silicide part of the impurity diffusion region 11 and part (a portion to be a contact formation region) of the polysilicon resistor 5. After selective removal of unreacted Ni, the semiconductor substrate 1 is subjected to rapid thermal annealing at 550° C. to stabilize the formed silicide. By the so-called salicide process described above, the first silicide layer 13 is formed on the impurity diffusion region 11 with a thickness of about 20 nm, and the silicide layer 14 for the resistor with a thickness of about 30 nm is formed on the contact formation region of the polysilicon resistor 5.

As shown in FIG. 3C, the second insulating film 15 of Si₃N₄ and the first interlayer insulating film 16 of NSG or the like are sequentially formed over the entire surface of the substrate, and then the first interlayer insulating film 16 is planarized by a chemical mechanical polishing (CMP) method.

Next, as shown in FIG. 3D, a second photoresist pattern (a second photoresist) 17 is formed on a region of the first interlayer insulating film 16 located above the polysilicon resistor 5. Using the formed second photoresist pattern 17 as a mask, etching is performed on a portion of the first interlayer insulating film 16 provided on the NMIS formation region. This exposes a portion of the second insulating film 15 provided above the polysilicon gate electrode 7.

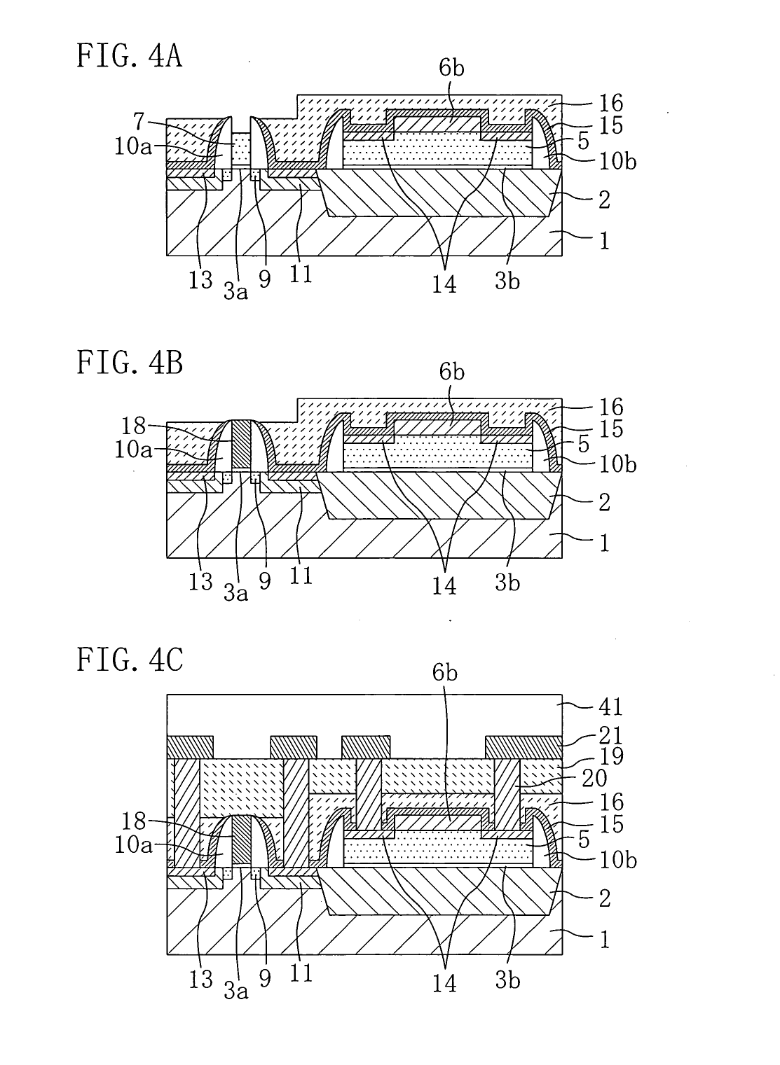

Subsequently, as shown in FIG. 4A, a portion of the second insulating film 15 provided above the polysilicon gate electrode 7 and the insulating film 6a on the gate electrode are removed by etching to expose the top surface of the polysilicon gate electrode 7.

As shown in FIG. 4B, over the entire surface of the substrate, for example, a Ni film with a thickness of 60 nm is formed by a sputtering method or the like. Then, the semiconductor substrate 1 is subjected to rapid thermal annealing at 340° C. to fully silicide the polysilicon gate electrode 7 on the gate insulating film 3a. After selective removal of unreacted Ni, the semiconductor substrate 1 is subjected to rapid thermal annealing at 520° C. to stabilize the formed silicide. By the so-called salicide process described above, the gate electrode 18 of Ni silicide having a thickness of about 110 nm is formed. The gate electrode 18 serves as a so-called fully silicided gate electrode (a FUSI gate electrode). In the case of the condition employed in the first embodiment, the gate electrode 18 is formed of NiSi. The salicide process shown in FIG. 3B can omit a second thermal treatment for stabilization of Ni silicide, but, more preferably, the salicide process used in this process step conducts second thermal treatment.

Thereafter, as shown in FIG. 4C, the second interlayer insulating film 19 is formed on the first interlayer insulating film 16, and the first interlayer insulating film 19 is planarized by a chemical mechanical polishing (CMP) method. Next, the plug 20 of tungsten (W) penetrating the first interlayer insulating film 16 and the second interlayer insulating film 19, the interconnect 21 connected to the plug 20, and the third interlayer insulating film 41 covering the second interlayer insulating film 19 and the interconnect 21 are formed sequentially. By the method described above, a semiconductor device can be fabricated which includes the MIS transistor with the fully silicided gate electrode 18 and the polysilicon resistor 5.

With this method, the first silicide layer 13 on the impurity diffusion region 11 and the silicide layer 14 for the resistor on the polysilicon resistor 5 can be formed simultaneously in the step shown in FIG. 3B. Therefore, the formation process for the silicide layers can be simplified as compared with the case where the first silicide layer 13 and the silicide layer 14 for the resistor are formed in different steps. Moreover, by forming the silicide layer 14 for the resistor provided in the contact formation region simultaneously with the first silicide layer 13 on the impurity diffusion region 11, only the top portion of the polysilicon resistor 5 can be silicided. This eliminates the phenomenon in which the silicide layer 14 for the resistor is formed to greatly expand into a portion thereof immediately below the insulating film 6b on the resistor. As a result, with the method of the first embodiment, the resistance value of the polysilicon resistor 5 can be controlled exactly as designed.

As described above, the semiconductor device which includes the MIS transistor with the FUSI electrode and the polysilicon resistor with the contact formation region silicided can be fabricated simply and stably by the method of the first embodiment.

In the first embodiment, description has been made of the example in which in the step shown in FIG. 2A, an n-type impurity is introduced into the polysilicon layer 4 that will be formed into the polysilicon gate electrode 7 later. However, an impurity does not necessarily have to be introduced into the portion of the polysilicon layer 4 serving as the polysilicon gate electrode 7.

In the first embodiment, description has been made of the example in which Ni is used as metal for forming the silicide layer. However, any metal capable of being allowed to react with Si, such as Pt, Yb or the like, to form silicide of a low resistance can be used thereas.

### Second Embodiment

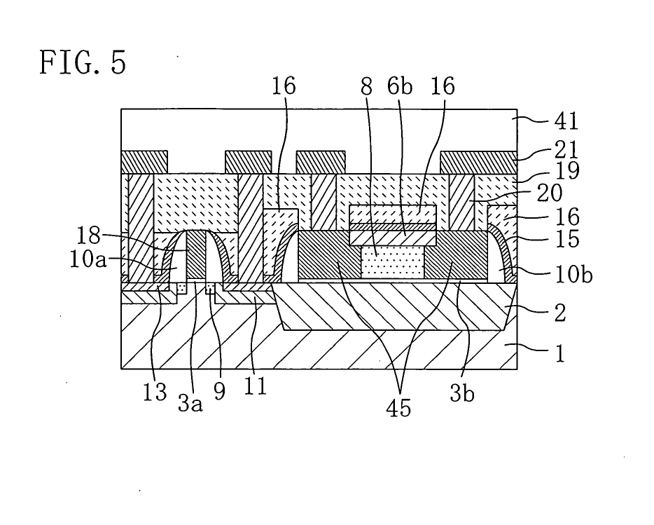

FIG. 5 is a sectional view showing a semiconductor device according to a second embodiment of the present invention. The semiconductor device of the second embodiment differs from the semiconductor device of the first embodiment in that of a polysilicon resistor 5, a silicide layer 45 for the resistor provided in a contact formation region is silicided to the bottom.

To be more specific, the semiconductor device of the second embodiment includes: a semiconductor substrate 1 made of silicon or the like; an isolation insulating film 2 surrounding an active region of the semiconductor substrate 1 and buried in the semiconductor substrate 1; a MIS (Metal-Insulator-Semiconductor) transistor formed on the active region of the semiconductor substrate 1; and a polysilicon resistor 8 provided above, for example, the isolation insulating film 2 with a first insulating film 3b interposed therebetween. Note that the first insulating film 3b does not necessarily have to be formed below the polysilicon resistor 8.

The MIS transistor includes a gate insulating film 3a, a gate electrode 18, a sidewall 10a,an extension region 9, an impurity diffusion region 11, and a first silicide layer 13. The gate insulating film 3a is provided on the semiconductor substrate 1 and made of a high-k material or the like. The gate electrode 18 is provided on the gate insulating film 3a of the high-k material or the like, and made of Ni silicide such as NiSi. The sidewall 10a is provided on each side surface of the gate electrode 18, and made of an insulative material such as SiO₂. The extension region 9 is formed in a region of the semiconductor substrate 1 located below each side of the gate electrode 18, and contains an n-type impurity at a low concentration. The impurity diffusion region 11 is provided in a region of the semiconductor substrate 1 located below the sides of the gate electrode 18 and the sidewall 10a, and serves as a source/drain region containing an n-type impurity at a higher concentration than that of the extension region 9. The first silicide layer 13 is provided on the impurity diffusion region 11, and made of Ni silicide. The first silicide layer 13 is connected through a plug 20 to an interconnect 21.

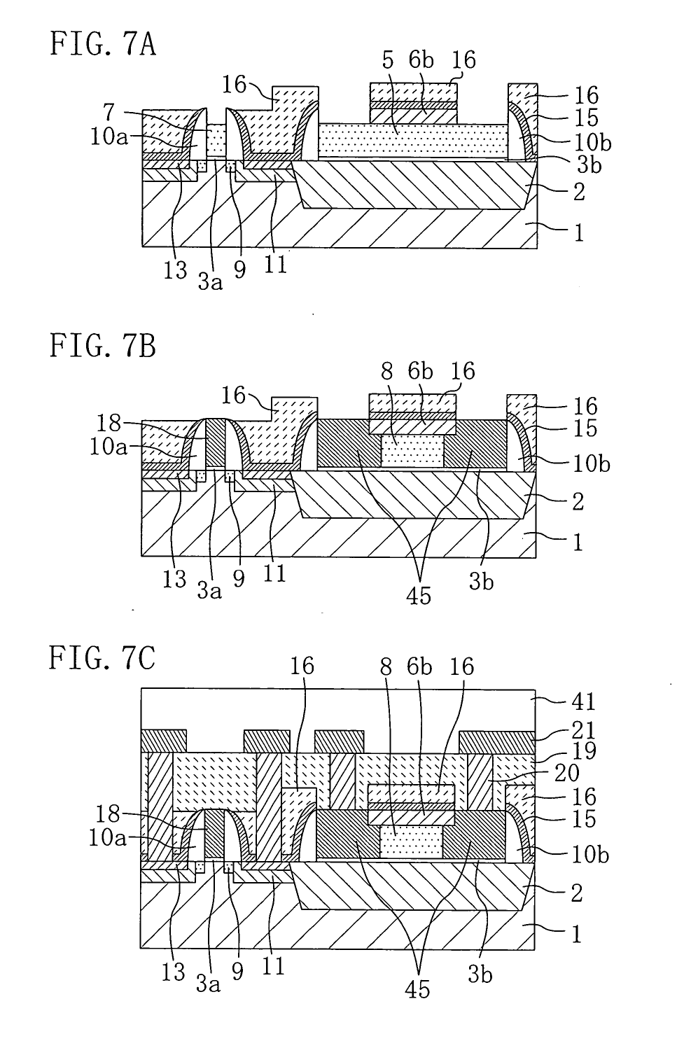

The polysilicon resistor 8 contains an n-type impurity at a low concentration (for example, about 3×10²⁰/cm³), and has a thickness of about 100 nm. An insulating film 6b on the resistor made of NSG or the like is provided on the polysilicon resistor 8. The silicide layer 45 for the resistor made of Ni silicide with a thickness of 110 nm is provided on each side surface of the polysilicon resistor 8 and each side surface of the insulating film 6b on the gate electrode. On each side surface of the silicide layer 45 for the resistor, a sidewall 10b is provided which is formed simultaneously with the sidewalls 10a. The silicide layer 45 for the resistor is formed by siliciding a portion of a polysilicon resistor 5 (see FIG. 7B) provided in the contact formation region to the bottom in contact with the first insulating film 3b. Therefore, no polysilicon remains below the silicide layer 45 for the resistor. Thus, this resistance element is composed of: a resistor region formed of the polysilicon resistor 8; and the contact formation region formed of the silicide layer 45 for the resistor made by siliciding the entire depthwise portion of the polysilicon resistor 8. In the fabrication process of the semiconductor device according to the second embodiment, the silicide layer 45 for the resistor is silicided simultaneously with the gate electrode 18, so that the thicknesses of the silicide layer 45 for the resistor and the gate electrode 18 become substantially equal.

The plug 20 penetrating a second interlayer insulating film 19 is connected to the silicide layer 45 for the resistor, and the plug 20 is connected to the interconnect 21 provided on the second interlayer insulating film 19.

The semiconductor device of the second embodiment is also formed with a second insulating film 15, a first interlayer insulating film 16, a second interlayer insulating film 19, and a third interlayer insulating film 41. The second insulating film 15 is made of Si₃N₄ or the like and-covers the first silicide layer 13, the sidewall 10a, the sidewall 10b, the insulating film 6b on the resistor, and the silicide layer 14 for the resistor of the MIS transistor. The first interlayer insulating film 16 is made of NSG or the like and provided on the second insulating film 15. The second interlayer insulating film 19 is made of NSG or the like and provided on the first interlayer insulating film 16. The third interlayer insulating film 41 is provided on the second interlayer insulating film 19 and the interconnect 21.

In the semiconductor device of the second embodiment, the whole of the gate electrode 18 is silicided, which prevents depletion of the gate electrode 18 occurring around the interface with the gate insulating film 3a. Furthermore, a portion of the impurity diffusion region 11 in contact with the plug 20 is silicided (as the first silicide layer 13), which reduces the contact resistance of the impurity diffusion region 11.

Next description will be made of a method for fabricating a semiconductor device according to the second embodiment of the present invention.

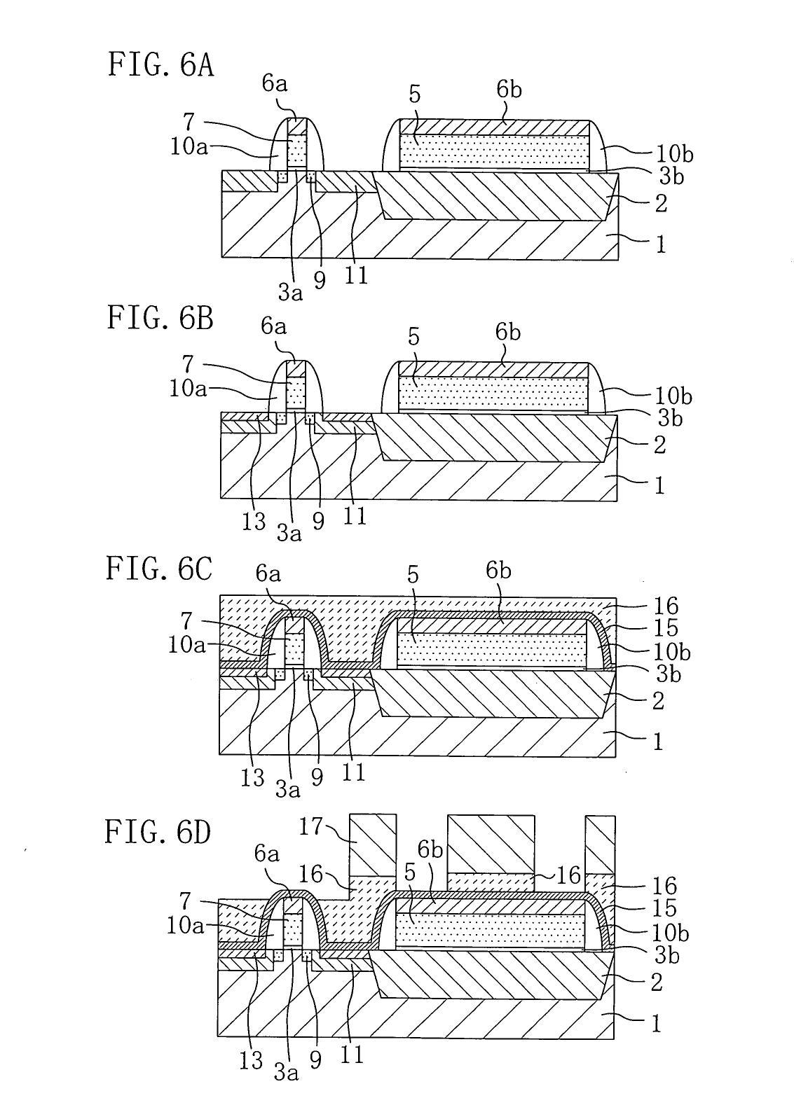

FIGS. 6A to 6D and 7A to 7C are sectional views showing a method for fabricating a semiconductor device according to the second embodiment.

First, by similar steps to those in FIGS. 2A to 2C described in the first embodiment, as shown in FIG. 6A, the sidewall 10a is formed on each side surface of the polysilicon gate electrode 7 and each side surface of the insulating film 6a on the gate electrode, and concurrently the sidewall 10b is formed on each side surface of the polysilicon resistor 5. Subsequently, using the polysilicon gate electrode 7 and the sidewall 10a as a mask, an n-type type impurity is implanted to form the impurity diffusion region 11 in a portion of an active region of the semiconductor substrate 1 located below the sides of the polysilicon gate electrode 7 and the sidewall 10a. Note that the thicknesses of the polysilicon gate electrode 7 and the polysilicon resistor 5 are 100 nm which is the same as those of the first embodiment.

Subsequently, as shown in FIG. 6B, by a so-called salicide process, the first silicide layer 13 made of Ni silicide with a thickness of about 20 nm is formed on the impurity diffusion region 11. Specifically, over the entire surface of the substrate, for example, a Ni film with a thickness of 11 nm is formed by a sputtering method or the like, and the resulting semiconductor substrate 1 is subjected to rapid thermal annealing at 320°0 C. to silicide the upper part of the impurity diffusion region 11. Then, after removal of unsilicided Ni, the semiconductor substrate 1 is subjected to rapid thermal annealing at 550° C. to stabilize the formed silicide layer. In the manner described above, the first silicide layer 13 is formed on the impurity diffusion region 11.

As shown in FIG. 6C, the second insulating film 15 of Si₃N₄ and the first interlayer insulating film 16 of NSG or the like are sequentially formed over the entire surface of the substrate, and then the first interlayer insulating film 16 is planarized by a chemical mechanical polishing (CMP) method.

Next, as shown in FIG. 6D, on the first interlayer insulating film 16, a second photoresist pattern 17 is formed which has an opening at the contact formation region of the polysilicon resistor 5 and at the region having been formed with the polysilicon gate electrode 7 on the semiconductor device. Thereafter, using the second photoresist pattern 17 as a mask, a portion of the first interlayer insulating film 16 is removed by etching to expose the portion of the second insulating film 15 provided above the polysilicon gate electrode 7 and the portion of the polysilicon resistor 5 provided above the contact formation region.

Subsequently, as shown in FIG. 7A, the second photoresist pattern 17 is removed. Then, using the first interlayer insulating film 16 as a mask, a portion of the second insulating film 15 and portions of the insulating film 6a on the gate electrode and the insulating film 6b on the resistor are removed to expose the top surface of the polysilicon gate electrode 7 and the top surface of the portion of the polysilicon resistor 5 located in the contact formation region.

As shown in FIG. 7B, over the entire surface of the substrate, for example, a Ni film with a thickness of 60 nm is formed by a sputtering method or the like. Then, rapid thermal annealing is performed at 340° C. to fully silicide the polysilicon gate electrode 7 on the gate insulating film 3a and the portion of the polysilicon resistor 5 provided in the contact formation region. After selective removal of unreacted Ni, the semiconductor substrate 1 is subjected to rapid thermal annealing at 520° C. The so-called salicide process described above simultaneously forms the gate electrode 18 of Ni silicide with a thickness of about 110 nm and the silicide layers 45 for the resistor with a thickness of about 110 nm provided on the first insulating film 3b and interposing the both sides of the polysilicon resistor 8. In this embodiment, the polysilicon resistor 8 indicates an unsilicided portion of the polysilicon resistor 5. In the case of the condition employed in the second embodiment, the gate electrode 18 is made of NiSi. The salicide process shown in FIG. 6B can omit a second thermal treatment for stabilization of Ni silicide, but, more preferably, the salicide process used in this process step conducts second thermal treatment. In addition, the silicide layer 45 for the resistor provided in this step is formed to expand into the polysilicon resistor 8 located below the insulating film 6b on the resistor, so that the width of the insulating film 6b on the resistor is desirably determined in consideration of the amount of expansion of the silicide layer 45 for the resistor.

Thereafter, as shown in FIG. 7C, the second interlayer insulating film 19 is formed on the first interlayer insulating film 16, and the first interlayer insulating film 19 is planarized by a chemical mechanical polishing (CMP) method. Next, the plug 20 penetrating the second interlayer insulating film 19, the interconnect 21 connected to the plug 20, and the third interlayer insulating film 41 covering the second interlayer insulating film 19 and the interconnect 21 are formed sequentially. By the method described above, a semiconductor device can be fabricated which includes the MIS transistor with the fully silicided gate electrode 18 and the polysilicon resistor 8.

With this method, in the step shown in FIG. 6B, the insulating film 6a on the gate electrode and the insulating film 6b on the resistor for patterning the polysilicon layer 4 can be used as a mask for silicide formation. Therefore, the semiconductor device including the FUSI electrode and the polysilicon resistor with the silicided contact formation region can be fabricated simply by a fewer number of steps than that in the first embodiment.

Moreover, with the method of the second embodiment, the silicide layer 45 for the resistor located on each side of the polysilicon resistor 8 and serving as the contact formation region is silicided so that the silicided portion reaches the bottom in contact with the first insulating film 3b. Therefore, even though the position of the plug 20 to be provided immediately above the silicide layer 45 for the resistor is shifted, the plug 20 can be brought into contact with the side surface of the silicide layer 45 for the resistor. This allows a sufficient contact area.

In the first and second embodiments, description has been made of the example of the polysilicon resistors 5 and 8 containing an n-type impurity. Alternatively, a polysilicon resistor containing a p-type impurity can be formed easily by conducting additional ion implantation. The type of conductivity and the concentration of the impurity introduced into the polysilicon resistor have less influence on formation of the silicide layer.

Also in the method of the second embodiment, description has been made of the example in which Ni silicide is formed like the method of the first embodiment. Alternatively, formation of another metal silicide can also provide the same effects.

In the first and second embodiments, the description of an unsilicided impurity diffusion layer (an impurity diffusion layer in an unsilicided region) and its formation process has been omitted. If needed, before silicidation of the impurity diffusion region 11, for example, an NSG film serving as an insulating film for inhibiting silicidation is formed in a region desired not to be silicided, and then silicidation is conducted. Thereby, an unsilicided impurity diffusion layer can be formed.

### Third Embodiment

Another example of the method for fabricating a semiconductor device according to the first embodiment will be described as a third embodiment of the present invention. Hereinafter, the description of the process steps previously described will be omitted and only a characteristic of the method of this embodiment will be illustrated.

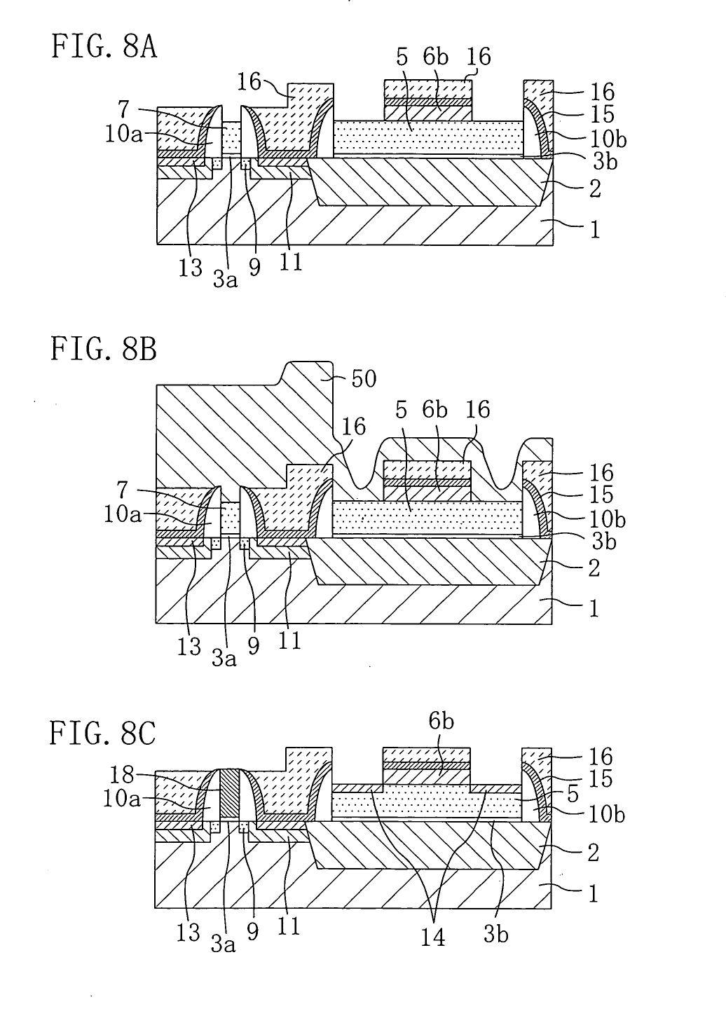

FIGS. 8A to SC are sectional views showing a method for fabricating a semiconductor device according to the third embodiment.

Referring to FIG. 8A, first, by the process steps in FIGS. 6A to 7A described in the second embodiment, the MIS transistor with the polysilicon gate electrode 7 and the polysilicon resistor 5 are formed over the semiconductor substrate 1. Note that the thicknesses of the polysilicon gate electrode 7 and the polysilicon resistor 5 are identical to those in the method of the second embodiment.

Next, as shown in FIG. 8B, over the entire surface of the substrate, for example, a Ni film 50 with a thickness of 60 nm is formed by a sputtering method or the like, and then only a portion of the Ni film 50 formed on or above the polysilicon resistor 5 is etched to have a thickness of, for example, 11 nm.

Subsequently, as shown in FIG. 8C, the resulting semiconductor substrate 1 is subjected to rapid thermal annealing at 340° C. to silicide the whole of the polysilicon gate electrode 7 and simultaneously silicide the top of a portion of the polysilicon resistor 5 provided in the contact formation region. After selective removal of unreacted Ni, the semiconductor substrate 1 is subjected to rapid thermal annealing at 520° C. By the so-called salicide process described above, the gate electrode 18 of Ni silicide with a thickness of about 110 nm is formed simultaneously with the silicide layer 14 for the resistor with a thickness of about 30 nm provided on the contact formation region of the polysilicon resistor 5.

Also by the method described above, the semiconductor device can be fabricated which has the same structure as the semiconductor device of the first embodiment of the present invention. With the method of the third embodiment, in the step shown in FIG. 8B, the Ni film 50 is made thinner on or above the polysilicon resistor 5 than on the polysilicon gate electrode 7. By this, in conducting rapid thermal annealing in the step shown in FIG. 8C, a smaller amount of Ni is supplied to the polysilicon resistor 5 than to the polysilicon gate electrode 7. Therefore, in forming the fully silicided gate electrode 18, the silicide layer 14 for the resistor can be simultaneously formed only on the top portion of the contact formation region of the polysilicon resistor 5, so that the semiconductor device can be fabricated simply by a fewer number of steps.

### Modification of Third Embodiment

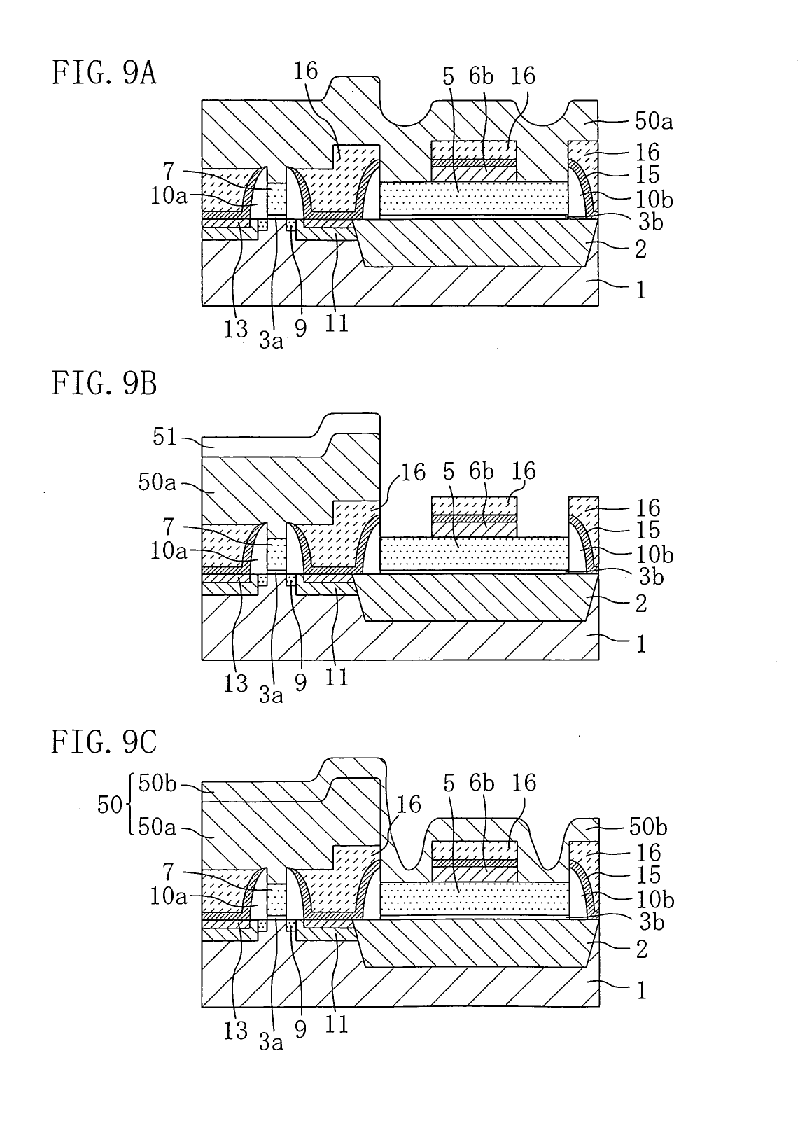

FIGS. 9A to 9C are sectional views showing a method for fabricating a semiconductor device according to one modification of the third embodiment of the present invention.

Referring to FIG. 9A, first, after the step shown in FIG. 8A, a Ni film 50a with a thickness of 49 nm is formed by a sputtering method or the like over the entire surface of the substrate.

Next, as shown in FIG. 9B, a mask 51 having an opening located only above the polysilicon resistor 5 is formed on the Ni film 50a, and then an exposed portion of the Ni film 50a is removed by etching. This procedure exposes the contact formation region of the polysilicon resistor 5.

Subsequently, as shown in FIG. 9C, after removal of the mask 51, a Ni film 50b with a thickness of 11 nm is formed by a sputtering method or the like over the entire surface of the substrate. In this modification, the Ni films 50a and 50b constitute the Ni film 50. This provides the semiconductor device of this modification with the same condition as the semiconductor device shown in FIG. 8B. Thereafter, the process steps described in the third embodiment can be carried out to fabricate the semiconductor device according to the first embodiment.

### Fourth Embodiment

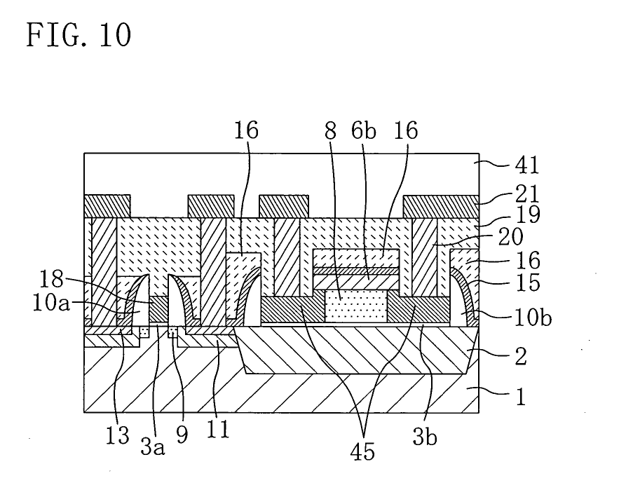

FIG. 10 is a sectional view showing a semiconductor device according to a fourth embodiment of the present invention. In this embodiment, description will be made of a semiconductor device which includes a p-type MIS transistor having a gate electrode fully silicided in its entirety and a polysilicon resistor having a contact formation region silicided entirely in the depth direction.

Referring to FIG. 10, the semiconductor device of the fourth embodiment differs from the semiconductor device according to the second embodiment in that the MIS transistor is p-type and a silicide layer 45 for the resistor and a polysilicon resistor 8 contain a p-type impurity. Thus, in the semiconductor device of the fourth embodiment, a p-type impurity is contained in a gate electrode 18 entirely silicided, a first silicide layer 13, an extension region 9, and an impurity diffusion region 11. The gate electrode 18 and the silicide layer 45 for the resistor are made of Ni silicide containing Ni larger in content than Si, such as Ni₂Si or Ni₃Si. The gate electrode 18 has a thickness of 80 nm, which is smaller than the thickness of the polysilicon resistor 8 (100 nm). The level of the top surface of the gate electrode 18 is lower than the level of the top portion of the sidewall 10a. The silicide layers 45 for the resistor formed in the contact formation region to interpose the polysilicon resistor 8 and coming into contact with the first insulating film 3b have thicknesses substantially equal to the thickness of the gate electrode 18. The members other than those described above are the same as the semiconductor device of the second embodiment, so that the description thereof will be omitted.

A method for fabricating a semiconductor device according to the fourth embodiment is basically the same as the method for fabricating a semiconductor device according to the second embodiment shown in FIGS. 6A to 7C. However, in an ion implantation step on the polysilicon layer 4 and an ion implantation step for forming the extension region 9 and the impurity diffusion region 11, a p-type impurity such as boron (B) is implanted thereinto. In addition, in the step shown in FIG. 7A, etching is performed to form the polysilicon resistor 5 in the contact formation region and the polysilicon gate electrode 7 to have a thickness of about 40 nm. Thereafter, a Ni film with a thickness of 60 nm is formed over the entire surface of the substrate, and then rapid thermal annealing is performed to fully silicide the polysilicon gate electrode 7 and the polysilicon resistor 5 of the contact formation region. After removal of unreacted Ni, the resulting semiconductor substrate 1 is subjected to rapid thermal annealing again to stabilize the gate electrode 18 and the silicide layer 45 for the resistor.

Ni silicide is known to have several different silicide phases such as Ni₂Si, Ni₃Si, and NiSi. These types of Ni silicide can be formed so that the ratio between the thickness of a polysilicon layer and the thickness of a Ni layer is adjusted to control the composition of a silicide layer. In.the fourth embodiment, the thickness of the Ni layer is made greater than the thicknesses of the polysilicon gate electrode 7 and the polysilicon resistor 5 of the contact formation region, whereby the gate electrode 18 and the silicide layer 45 for the resistor can be made of Ni₂Si. From this fact, in the fabrication method of the fourth embodiment, the thicknesses of the polysilicon gate electrode 7 and the polysilicon resistor of the contact formation region are made thinner than those in the fabrication method of the second embodiment. This provides a decreased thickness of the gate electrode 18 smaller than the thickness of the polysilicon resistor 8 formed below the insulating film 6b on the resistor.

Since in the semiconductor device of the fourth embodiment, a p-type impurity is introduced into the polysilicon resistor 8, the resulting polysilicon resistor 8 has a higher resistance than that of the case where an n-type impurity is introduced thereinto. This enables reduction of the plane area of the polysilicon resistor 8 as compared to the resistor containing an n-type impurity.

In the method of the fourth embodiment, description has been made of the example in which the portion of the polysilicon resistor 5 provided in the contact formation region is silicided to the bottom. Alternatively, a method as shown in the third embodiment and its modification may be employed to silicide only the top portion of the polysilicon resistor 5 provided in the contact formation region.

### Fifth Embodiment

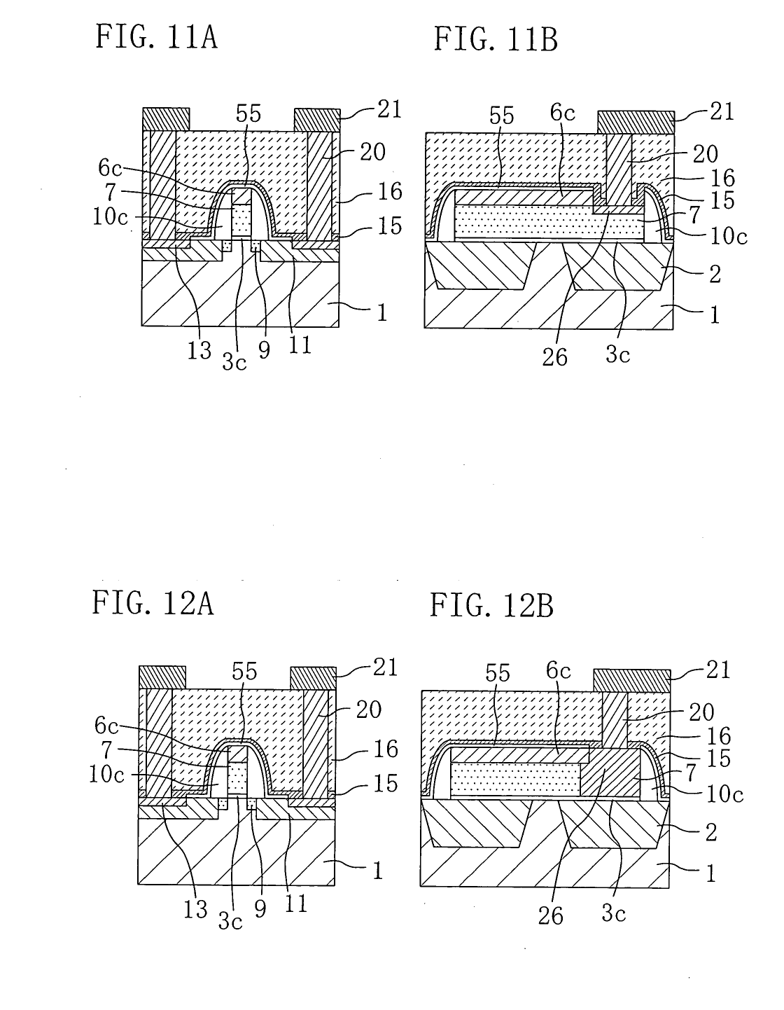

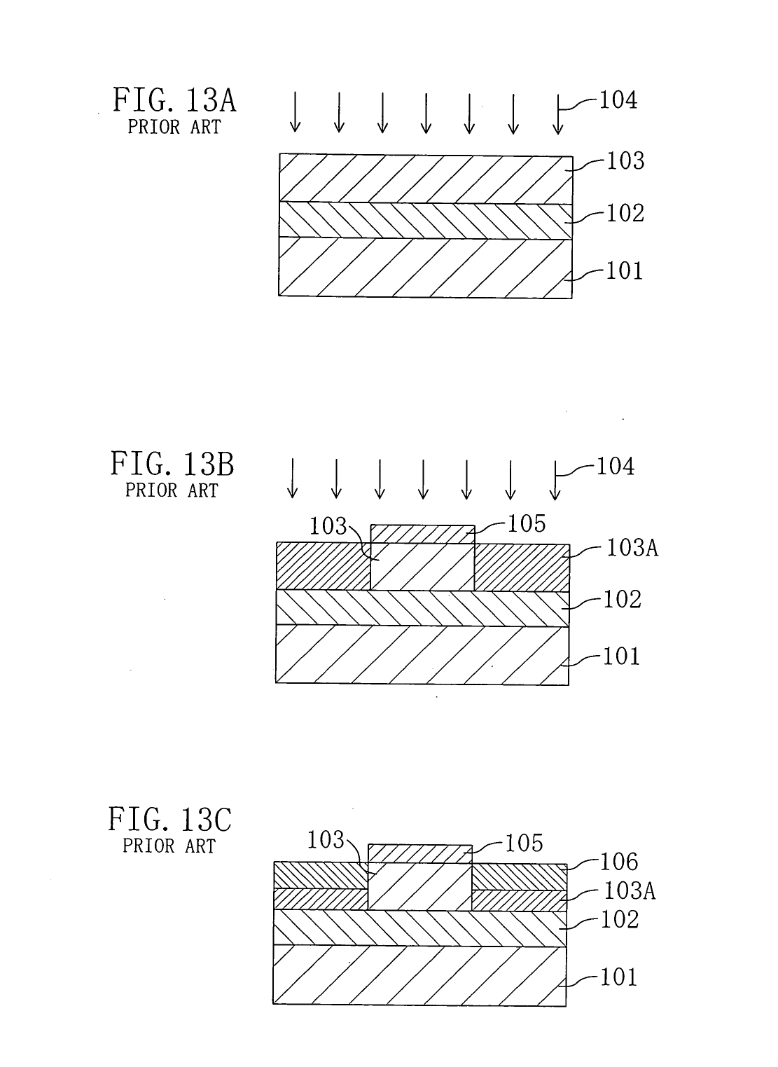

FIG. 11A is a sectional view of a semiconductor device according to a fifth embodiment of the present invention, which is taken along the gate length direction, while FIG. 11B is a sectional view of the semiconductor device in which a gate electrode is taken along the gate width direction.

The semiconductor device of the fifth embodiment includes, in addition to the polysilicon resistor 5 and the MIS transistor having a gate electrode 18 (see FIG. 1) silicided in its entirety which have been described in the first embodiment, a MIS transistor having a polysilicon gate electrode 7 in which a contact formation region is silicided and the other region is not silicided.

To be more specific, as shown in FIGS. 11A and 11B, the semiconductor device of the fifth embodiment includes a semiconductor substrate 1, an isolation insulating film 2, and a MIS transistor formed on an active region of the semiconductor substrate 1. The MIS transistor includes a polysilicon gate electrode 7, a sidewall 10c, an extension region 9, an impurity diffusion region 11, a first silicide layer 13, a second silicide layer 26, and a third insulating film 6c. The polysilicon gate electrode 7 is provided to extend from the top of the semiconductor substrate 1 to the top of the isolation insulating film 2 with a gate insulating film 3c interposed therebetween. The sidewall 10c is provided on each side surface of the polysilicon gate electrode 7. The extension region 9 contains an n-type impurity at a low concentration. The impurity diffusion region 11 is provided in a region of the semiconductor substrate 1 located below the sides of the polysilicon gate electrode 7 and the sidewall 10c, and contains an n-type impurity at a higher concentration than that of the extension region 9. The first silicide layer 13 of Ni silicide is provided in the top of a portion of the impurity diffusion region 11 to be spaced away from the sidewall 10c. The second silicide layer 26 with a thickness of 30 nm is formed in the contact formation region of the polysilicon gate electrode 7. The third insulating film 6c of NSG or the like is provided on the polysilicon gate electrode 7. A second insulating film 15, a first interlayer insulating film 16, a plug 20, an interconnect 21, and the like are sequentially formed over the third insulating film 6c, the sidewall 10c, and the impurity diffusion region 11. The contact formation region of the polysilicon gate electrode 7 is formed above the isolation insulating film 2. The second silicide layer 26 provided on the contact formation region of the polysilicon gate electrode 7 has almost the same thickness as the first suicide layer 13. Unlike the MIS transistor of the first embodiment, an insulating film 55 for forming an opening in the impurity diffusion region 11 and the contact formation region of the polysilicon gate electrode 7 is provided between the second insulating film 15 and part of the impurity diffusion region 11, the sidewall 10c, and the third insulating film 6c.

The semiconductor device of the fifth embodiment is characterized in that in the MIS transistor provided on part of the semiconductor substrate 1, the insulating film 55 inhibits provision of the first silicide layer 13 on a portion of the impurity diffusion region 11 closer to the polysilicon gate electrode 7, and thereby the first silicide layer 13 is not in contact with the sidewall 10c. This characteristic provides the MIS transistor with an improved breakdown voltage between a source and a drain. Such a MIS transistor is employed for an electrostatic discharge protection circuit (ESD protection circuit) or the like. Note that since the second silicide layer is provided on the contact formation region of the polysilicon gate electrode 7, the MIS transistor shown in FIG. 11 has a reduced resistance value between the polysilicon gate electrode 7 and the plug 20. In the semiconductor device of the fifth embodiment, the second silicide layer 26 provided on the contact formation region of the polysilicon gate electrode 7 is prevented from expanding into an unsilicided region, so that reduction in the layout size can be attained.

The semiconductor device of the fifth embodiment can be fabricated by a method similar to the fabrication method of the first embodiment. For example, in the case where the MIS transistor and the polysilicon resistor 5 shown in FIG. 1 and the MIS transistor of the fifth embodiment shown in FIG. 11 are formed over the same substrate, an opening for exposing the contact formation region of the polysilicon gate electrode 7 shown in the FIG. 11B is formed in the first photoresist pattern 12 in the step shown in FIG. 3A. Thereafter, before entering the step shown in FIG. 3B, the insulating film 55 serving as a mask for inhibiting silicidation is formed in advance over the semiconductor substrate 1 which contains a portion of the impurity diffusion region 11 in FIG. 11 located closer to the polysilicon gate electrode 7. This mask serves as a mask for forming the first suicide layer 13 to be spaced away from the polysilicon gate electrode 7 and the sidewall 10c. Then, it is recommended that in the step shown in FIG. 3B, the first silicide layer 13 and the second silicide layer 26 of the MIS transistor of the fifth embodiment are formed simultaneously with the first silicide layer 13 of the MIS transistor according to the first embodiment. Moreover, it is recommended that in the step of siliciding the polysilicon gate electrode 7 shown in FIG. 4B, the polysilicon gate electrode 7 of the MIS transistor of the fifth embodiment is kept from being exposed. With the method described above, the MIS transistor including the polysilicon gate electrode 7 and having an improved breakdown voltage, the MIS transistor including the FUSI electrode, and the polysilicon resistor 5 can be formed without increasing the number of process steps greatly.

Note that the semiconductor device of the fifth embodiment can be fabricated by a method similar to the fabrication method of the third embodiment.

The above description is the example in which on the semiconductor substrate 1, the MIS transistor of the fifth embodiment is provided together with the MIS transistor with the FUSI electrode and the polysilicon resistor. Alternatively, on the semiconductor substrate 1, the MIS transistor of the fifth embodiment may be provided singly, or together with only the MIS transistor having the silicided gate electrode and without providing the polysilicon resistor.

### Sixth Embodiment

FIG. 12A is a sectional view of a semiconductor device according to a sixth embodiment of the present invention, which is taken along the gate length direction, while FIG. 12B is a sectional view of the semiconductor device in which a gate electrode is taken along the gate width direction.

The semiconductor device of the sixth embodiment includes, in addition to the MIS transistor having the gate electrode 18 (see FIG. 5) silicided in its entirety and the polysilicon resistor 8 interposed between the silicide layers 45 for the resistor which have been described in the second embodiment, a MIS transistor having a polysilicon gate electrode 7 in which a contact formation region is silicided to the bottom and the other region is not silicided.

The MIS transistor of the sixth embodiment differs from the MIS transistor of the fifth embodiment in that the second silicide layer 26 made by siliciding a portion of the polysilicon gate electrode 7 provided in the contact formation region has a greater thickness than the polysilicon gate electrode 7. Another structure is identical to that of the semiconductor device of the fifth embodiment.

Also in the semiconductor device of the sixth embodiment, the first silicide layer 13 is not provided on the portion of the impurity diffusion region 11 closer to the polysilicon gate electrode 7, and thereby the first silicide layer 13 is not in contact with the sidewall 10c. This provides the MIS transistor of the sixth embodiment with an improved breakdown voltage between a source and a drain. Thus, the MIS transistor of the sixth embodiment is preferably employed for an ESD protection circuit or the like.

The MIS transistor of the sixth embodiment can be fabricated by a method similar to the fabrication method of the second embodiment. For example, in the case where the MIS transistor and the polysilicon resistor 8 shown in FIG. 5 and the MIS transistor of the sixth embodiment shown in FIG. 12 are formed over the same substrate, in the step shown in FIG. 7A, the contact formation region of the polysilicon gate electrode 7 is exposed in the MIS transistor of the sixth embodiment. Thereafter, before entering the step shown in FIG. 7B, the insulating film 55 serving as a mask for inhibiting silicidation is formed in advance over the semiconductor substrate 1 which contains a portion of the impurity diffusion region 11 in FIG. 12 located closer to the polysilicon gate electrode 7. Then, in the step shown in FIG. 7B, the second silicide layer 26 is formed simultaneously with the silicided gate electrode 18 and the silicide layer 45 for the resistor.

The above description is the example in which on the semiconductor substrate 1, the MIS transistor of the sixth embodiment is provided together with the MIS transistor with the FUSI electrode and the polysilicon resistor. Alternatively, on the semiconductor substrate 1, the MIS transistor of the sixth embodiment may be provided singly, or together with only the MIS transistor having an unsilicided gate electrode.

With the semiconductor device of the sixth embodiment, the contact formation region of the polysilicon gate electrode 7 is silicided to the bottom. Therefore, even though the position at which the contact (the plug 20) is formed is shifted from the polysilicon gate electrode 7, the area of the side wall of the second silicide layer 26 in contact with the plug can be secured sufficiently. This prevents rise in the contact resistance between the polysilicon gate electrode 7 and the plug 20.

As described above, the present invention can be employed for all types of semiconductor devices including a FUSI gate electrode and a polysilicon resistor, and is useful for the securing of analog properties as a system LSI and of the performance of an ESD protection circuit.

What is claimed is:

1. A semiconductor device comprising:
a semiconductor substrate;
a first MIS transistor which includes a first gate insulating film provided on the semiconductor substrate; a first gate electrode provided on the first gate insulating film and made of metal silicide; and a first impurity diffusion region formed in a region of the semiconductor substrate located below each side of the first gate electrode; and
a resistance element formed over an isolation region provided in the semiconductor substrate and having a resistor of polysilicon,
wherein a contact formation region of the resistance element is formed at least at its top with a first silicide layer.

2. The device of claim 1,
wherein the first MIS transistor further includes a second silicide layer provided on the first impurity diffusion region.

3. The device of claim 1,
wherein the first silicide layer is formed on a polysilicon layer provided in the contact formation region of the resistance element.

4. The device of claim 1,
wherein an entire depthwise portion of the contact formation region of the resistance element is formed of the first silicide layer.

5. The device of claim 1,
wherein the first silicide layer has a greater thickness than the resistor.

6. The device of claim 1, further comprising a second MIS transistor which includes: a second gate insulating film provided on the semiconductor substrate; a second gate electrode of polysilicon provided on the second gate insulating film and formed, at least on the top of the contact formation region, with a third silicide layer; and a second impurity diffusion region formed in a region of the semiconductor substrate located below each side of the second gate electrode.

7. The device of claim 6,
wherein the second MIS transistor further includes: a sidewall provided on a side surface of the second gate electrode; and a fourth silicide layer provided on the second impurity diffusion region to be spaced away from the sidewall.

8. The device of claim 6,
wherein an entire depthwise portion of the contact formation region of the second gate electrode is formed of the third silicide layer.

9. The device of claim 1,
wherein the first impurity diffusion region and the resistor contain a p-type impurity.

10. A semiconductor device comprising:
a semiconductor substrate;
an isolation region provided in the semiconductor substrate;
a first MIS transistor which includes: a first gate insulating film provided on the semiconductor substrate; a first gate electrode provided on the first gate insulating film and made of metal silicide; and a first impurity diffusion region formed in a region of the semiconductor substrate located below each side of the first gate electrode; and
a second MIS transistor which includes: a second gate insulating film provided on the semiconductor substrate; a second gate electrode of polysilicon provided on the second gate insulating film and formed, at least at the top of a contact formation region thereof, with a silicide layer; and a second impurity diffusion region formed in a region of the semiconductor substrate located below each side of the second gate electrode.

11. A method for fabricating a semiconductor device which includes: a first MIS transistor made of metal silicide and having a first gate electrode; and a resistance element having a resistor of polysilicon, the method comprising:
the step (a) of forming an isolation region in a semiconductor substrate;
the step (b) of forming, after the step (a), a first gate insulating film on the semiconductor substrate;
the step (c) of forming, after the step (b), a polysilicon layer over the semiconductor substrate;
the step (d) of patterning the polysilicon layer to form a polysilicon layer for the first gate electrode on the first gate insulating film and a polysilicon layer for the resistance element over the isolation region;
the step (e) of forming a first impurity diffusion region in a region of the semiconductor substrate located below each side of the polysilicon layer for the first gate electrode;
the step (f) of siliciding, after the step (e), at least the top of a contact formation region of the resistance element of the polysilicon layer for the resistance element to form a first silicide layer; and
the step (g) of siliciding, after the step (e), the whole of the polysilicon layer for the first gate electrode to form the first gate electrode.

12. The method of claim 11, wherein in the step (f), in forming the first silicide layer, a second silicide layer is simultaneously formed by siliciding the top of the first impurity diffusion region.

13. The method of claim 11,
wherein the steps (f) and (g) of silicidation are carried out simultameously to form the first gate electrode and the first silicide layer at a time.

14. The method of claim 13, further comprising, after the step (e) and before the steps (f) and (g), the step of forming a metal film over the entire surface of the substrate, the metal film having a smaller thickness over the polysilicon layer for the resistance element than over the polysilicon layer for the first gate electrode,
wherein in the steps (f) and (g), by thermal treatment, the metal film is allowed to react with the entire area of the polysilicon layer for the first gate electrode, thereby forming the first gate electrode, and simultaneously the metal film is allowed to react with the contact formation region of the polysilicon layer for the resistance element, thereby forming the first silicide layer.

15. The method of claim 11, w
herein the semiconductor device further comprises a second MIS transistor which includes a second gate electrode of polysilicon having a third silicide layer formed at least on the top of the contact formation region,
in the step (b), a second gate insulating film is formed on the semiconductor substrate,
in the step (d), the polysilicon layer is patterned to form a polysilicon layer for the second gate electrode on the second gate insulating film,
in the step (e), a second impurity diffusion region is formed in a region of the semiconductor substrate located below each side of the polysilicon layer for the second gate electrode, and
in the step (f), at the same time of formation of the first silicide layer, the top of a contact formation region of the second gate electrode of the polysilicon layer for the second gate electrode is silicided to form a third silicide layer.

16. The method of claim 15, further comprising, after the step (d) and before the step (e), forming a sidewall on a side surface of the polysilicon layer for the second gate electrode,
wherein in the step (f), at the same time of formation of the first silicide layer, the top of the second impurity diffusion region is silicided to form a fourth silicide layer to be spaced away from the sidewall.

17. The method of claim 11,
wherein the semiconductor device further comprises a second MIS transistor which includes a second gate electrode of polysilicon having a third silicide layer formed at least on the top of the contact formation region,
in the step (b), a second gate insulating film is formed on the semiconductor substrate,
in the step (d), the polysilicon layer is patterned to form a polysilicon layer for the second gate electrode on the second gate insulating film,
in the step (e), a second impurity diffusion region is formed in a region of the semiconductor substrate located below each side of the polysilicon layer for the second gate electrode, and
in the step (g), at the same time of formation of the first gate electrode, an entire depthwise portion of a contact formation region of the second gate electrode of the polysilicon layer for the second gate electrode is silicided to form a third silicide layer.

18. The method of claim 17, further comprising, after the step (d) and before the step (e), forming a sidewall on a side surface of the polysilicon layer for the second gate electrode,
wherein after the step (e), the top of the second impurity diffusion region is silicided to form a fourth silicide layer to be spaced away from the sidewall.

19. A method for fabricating a semiconductor device which includes: a first MIS transistor made of metal silicide and having a first gate electrode; and a second MIS transistor having a second gate electrode of polysilicon with a first silicide layer formed at least on the top of a contact formation region, the method comprising:
the step (a) of forming an isolation region in a semiconductor substrate;
the step (b) of forming, after the step (a), a first gate insulating film and a second gate insulating film on the semiconductor substrate;
the step (c) of forming, after the step (b), a polysilicon layer over the semiconductor substrate;
the step (d) of patterning the polysilicon layer to form a polysilicon layer for the first gate electrode on the first gate insulating film and a polysilicon layer for the second gate electrode on the second gate insulating film;
the step (e) of forming a first impurity diffusion region in a region of the semiconductor substrate located below each side of the polysilicon layer for the first gate electrode and a second impurity diffusion region in a region of the semiconductor substrate located below each side of the polysilicon layer for the second gate electrode;
the step (f) of siliciding, after the step (e), at least the top of a contact formation region of the second gate electrode of the polysilicon layer for the second gate electrode to form the first silicide layer; and
the step (g) of siliciding, after the step (e), the whole of the polysilicon layer for the first gate electrode to form the first gate electrode.

20. The method of claim 19,
wherein in the step (f), in forming the first silicide layer, a second silicide layer is simultaneously formed by siliciding the top of the first impurity diffusion region.

21. The method of claim 19,
wherein the steps (f) and (g) of silicidation are carried out simultameously to form the first gate electrode and the first silicide layer at a time.
